(19) United States
(12) Patent Application Publication
(10) Pub. No.: US 2008/0283728 A1
(43) Pub. Date: Nov. 20, 2008

(54) Solid-state image pickup device and a method of manufacturing the same, and image pickup apparatus

(75) Inventor: Susumu Inoue, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/081,531

(22) Filed: Apr. 17, 2008

(30) Foreign Application Priority Data
May 15, 2007 (JP) 2007-128992

(51) Int. Cl. H01L 27/00; H01L 21/00

(52) U.S. Cl. 250/208.1; 438/48

(57) ABSTRACT

Disclosed herein is a solid-state image pickup device, including: a first pixel for receiving a visible light of an incident light to subject the visible light to photoelectric conversion; a second pixel for receiving the visible light and a near-infrared light of the incident light to subject each of the visible light and the near-infrared light to the photoelectric conversion; a color filter layer; and an infrared light filter layer for absorbing or reflecting an infrared light, and transmitting the visible light.

### CROSS REFERENCES TO RELATED APPLICATIONS

The present invention contains subject matter related to Japanese Patent Application JP 2007-128992 filed in the Japan Patent Office on May 15, 2007, the entire contents of which being incorporated herein by reference.

### BACKGROUND OF THE INVENTION

1. Field of the Invention

The present invention relates to a solid-state image pickup device and a method of manufacturing the same, and an image pickup apparatus.

2. Description of the Related Art

At the present time, an infrared fitting (IR-Fitting) technique is in the progress of being developed aimed at promoting a high sensitivity of image sensors. The feature of the IR-fitting is that a visible light and a near-infrared light are simultaneously taken in an image sensor, thereby realizing high-sensitivity promotion for an image sensor. For this reason, a pixel (hereinafter referred to as “an A pixel”) in which the visible light and the near-infrared light are simultaneously taken exists in the image sensor in addition to the normal RGB pixels. This technique, for example, is described in Japanese Patent Laid-Open No. 2006-190958 (hereinafter referred to as Patent Document 1).

In the normal image sensor, an infrared light cutting filter is provided over the entire surface on the image sensor. Thus, only the visible light having a wavelength of about 400 to about 700 nm is taken in each of the pixels to be subjected to photoelectric conversion. On the other hand, with the IR-fitting technique, no normal infrared light cutting filter is provided in the image sensor. In addition thereto, the visible light and the near-infrared light can be taken in the image sensor because a color filter or the like is not provided over the A pixel. On the other hand, only the visible light is selectively taken in each of the RGB pixels. As a result, a filter for selectively cutting the near-infrared light needs to be provided in addition to the color filter normally used. A solid-state image pickup device including a multilayer film (hereinafter referred to as “an MLT film”) for selectively reflecting the near-infrared light is disclosed in order to realize this function. In this case, the MLT film is formed by laminating a plurality of films having predetermined thicknesses, respectively, on top of one another. This solid-state image pickup device, for example, is disclosed in Patent Document 1.

The MLT film described above is structured so that a thickness, d, of each of the laminated films meets an expression of d=λ/(4n) where λ is a central wavelength of a reflected light, and n is a refractive index of corresponding one of the laminated films.

When the MLT film having nine to 11 layers is formed from a silicon oxide film and a silicon nitride film in order to reflect a light, for example, having a central wavelength of 900 nm, a total thickness of the MLT film is in the range of 1 to 1.5 μm.

In addition, a patterning process for the MLT film, and a planarizing process for an insulating layer become necessary for the purpose of forming the MLT film within a light condensing structure of each of the pixels. As a result, the addition of the MLT film results in that the light condensing structure of each of the pixels becomes about 1.5 to about 2.5 μm thicker than that having the MLT film.

The increase in thickness of the light condensing structure makes it difficult to condense the light on each of the pixels. As a result, there are caused the various problems such as color mixture between the adjacent pixels, deterioration of shading, and reduction in sensitivity to an F-value light. In particular, a quantity of light is more in the A pixel in which the visible light and the near-infrared light are simultaneously taken than in each of the RGB pixels. Therefore, as shown in FIG. 7, an influence of a color mixture component leading from the A pixel into the pixel adjacent thereto is large, which exerts a large influence such as deterioration of color reproducibility on the adjacent pixel.

### SUMMARY OF THE INVENTION

The problem to be solved is that it becomes difficult to condense the light on each of the pixels owing to the increase in thickness of the film(s) on each of the pixels resulting from the formation of the MLT film, thus causing the problem about the color mixture between the adjacent pixels. In particular, the quantity of light is more in the A pixel in which the visible light and the near-infrared light are simultaneously taken than in each of the RGB pixels. Therefore, the influence of the color mixture component leading from the A pixel into the pixel adjacent thereto is large, which exerts the large influence such as the deterioration of the color reproducibility on the adjacent pixel.

In the light of the foregoing, it is therefore desire to provide a solid-state image pickup device which is capable of realizing high sensitivity promotion with excellent color reproducibility without causing a problem about color mixture even when an infrared light filter layer, such as an MLT film for selectively cutting a near-infrared light, for absorbing or deflecting an infrared light, and transmitting a visible light, and a method of manufacturing the same, and an image pickup apparatus.

In order to attain the desire described above, according to an embodiment of the present invention, there is provided a solid-state image pickup device, including: a first pixel for receiving a visible light of an incident light to subject the visible light to photoelectric conversion; a second pixel for receiving the visible light and a near-infrared light of the incident light to subject each of the visible light and the near-infrared light to the photoelectric conversion; and a color filter layer, and an infrared light filter layer for absorbing or reflecting an infrared light, and transmitting the visible light, the color filter layer and the infrared light filter layer being formed in order from a light incidence side of an optical path of the incident light made incident to the first pixel; in which the infrared light filter layer has an opening portion formed by opening an optical path of the incident light made incident to the second pixel; and an optical waveguide for guiding the incident light in a direction to the second pixel through the opening portion is formed.

In the embodiment of the present invention, the infrared light filter layer has the opening portion formed by opening the optical path of the incident light made incident to the second pixel, and the optical waveguide for guiding the incident light in the direction to the second pixel through the opening portion is formed. Therefore, an influence of a color mixture component leaking from the second pixel for receiving the visible light and the near-infrared light to subject each of the visible light and the near-infrared light to the photoelectric conversion is reduced, and thus the sensitivity of the second pixel is enhanced.

According to another embodiment of the present invention, there is provided a method of manufacturing a solid-state image pickup device having a substrate, a first pixel for receiving a visible light of an incident light to subject the visible light to photoelectric conversion, a second pixel for receiving the visible light and a near-infrared light of the incident light to subject each of the visible light and the near-infrared light to the photoelectric conversion, and an optically-transparent insulating film covering the first pixel and the second pixel being formed on the substrate, the method of manufacturing a solid-state image pickup device including the steps of: forming an infrared light filter layer for absorbing or reflecting an infrared light, and transmitting the visible light in a region except for an optical path of the incident light made incident to the second pixel, the region being located on the insulating film; forming an opening portion in the optical path of the incident light made incident to the second pixel so as to extend completely through the infrared light filter layer; and forming an optical waveguide for guiding the incident light in a direction to the second pixel through the opening portion in the optically-transparent insulating film by utilizing the opening portion.

In the another embodiment of the present invention, the opening portion is formed in the optical path of the incident light made incident to the second pixel so as to extend completely through the infrared light filter layer, and the optical waveguide for guiding the incident light in the direction to the second pixel is formed by utilizing the opening portion. Therefore, an influence of a color mixture component leaking from the second pixel for receiving the visible light and the near-infrared light to subject each of the visible light and the near-infrared light to the photoelectric conversion into the adjacent pixel is reduced, and thus the sensitivity of the second pixel is enhanced.

According to still another embodiment of the present invention, there is provided an image pickup apparatus, including: a condensing optical portion for condensing an incident light; a solid-state image pickup device for receiving the incident light condensed by the condensing optical portion to subject the condensed incident light thus received to photoelectric conversion; and a signal processing portion for processing a signal obtained through the photoelectric conversion, the solid-state image pickup device including: a first pixel for receiving a visible light of an incident light to subject the visible light to photoelectric conversion; a second pixel for receiving the visible light and a near-infrared light of the incident light to subject each of the visible light and the near-infrared light to the photoelectric conversion; and a color filter layer, and an infrared light filter layer for absorbing or reflecting an infrared light, and transmitting the visible light, the color filter layer and the infrared light filter layer being formed in order from a light incidence side of an optical path of the incident light made incident to the first pixel; in which the infrared light filter layer has an opening portion formed by opening an optical path of the incident light made incident to the second pixel; and an optical waveguide for guiding the incident light in a direction to the second pixel through the opening portion is formed.

In the still another embodiment of the present invention, the solid-state image pickup device according to the embodiment of the present invention is used as the solid-state image pickup device for receiving the incident light condensed by the condensing optical portion. Therefore, an influence, of a color mixture component, in which the incident light leaks from the second pixel into the adjacent pixel is reduced, and thus a sensitivity of the second pixel is enhanced.

According to the embodiment of the present invention, the influence of the color mixture component leaking from the second pixel into the adjacent pixel is reduced. As a result, even when the infrared light filter layer for absorbing or reflecting the infrared light, and transmitting the visible light is formed, it is possible to prevent the problem about the color mixture from being caused. Consequently, there is offered an advantage that it is possible to suppress the deterioration of the color reproducibility. In addition, the incident light can be efficiently condensed on the second pixel by the optical waveguide. Consequently, there is offered an advantage that the high sensitivity of the solid-state image pickup device can be realized.

In addition, according to another embodiment of the present invention, the influence of the color mixture component leaking from the second pixel into the adjacent pixel is reduced. As a result, even when the infrared light filter layer for absorbing or reflecting the infrared light, and transmitting the visible light is formed, it is possible to prevent the problem about the color mixture from being caused. Consequently, there is offered an advantage that it is possible to suppress the deterioration of the color reproducibility. In addition, the incident light can be efficiently condensed on the second pixel by the optical waveguide. Consequently, there is offered an advantage that the high sensitivity of the solid-state image pickup device can be realized.

Also, according to the still another embodiment of the present invention, since the influence of the color mixture component leaking from the second pixel into the adjacent pixel is reduced and thus a sensitivity of the second pixel is enhanced, there is offered an advantage that it is possible to obtain a high-sensitivity image having the excellent color reproducibility.

### BRIEF DESCRIPTION OF THE DRAWINGS

FIG. 1 is a cross sectional view showing a schematic structure of a solid-state image pickup device according to a first embodiment of the present invention;

FIG. 2 is a cross sectional view showing a schematic structure of a modified example of the solid-state image pickup device according to the first embodiment of the present invention;

FIG. 3 is a cross sectional view showing a schematic structure of a solid-state image pickup device according to a second embodiment of the present invention;

FIGS. 4A to 4F are respectively cross sectional views showing manufacturing processes in a method of manufacturing a solid-state image pickup device according to a first embodiment of the present invention;

FIG. 5 is a cross sectional view showing manufacturing processes in a method of manufacturing a solid-state image pickup device according to a second embodiment of the present invention;

FIG. 6 is a block diagram showing an image pickup apparatus according to an embodiment of the present invention; and

FIG. 7 is a schematically structural cross sectional view showing a problem involved in a solid-state image pickup device in the related art.

### DETAILED DESCRIPTION OF THE PREFERRED EMBODIMENTS

Preferred embodiments of the present invention will be described in detail hereinafter with reference to the accompanying drawings.

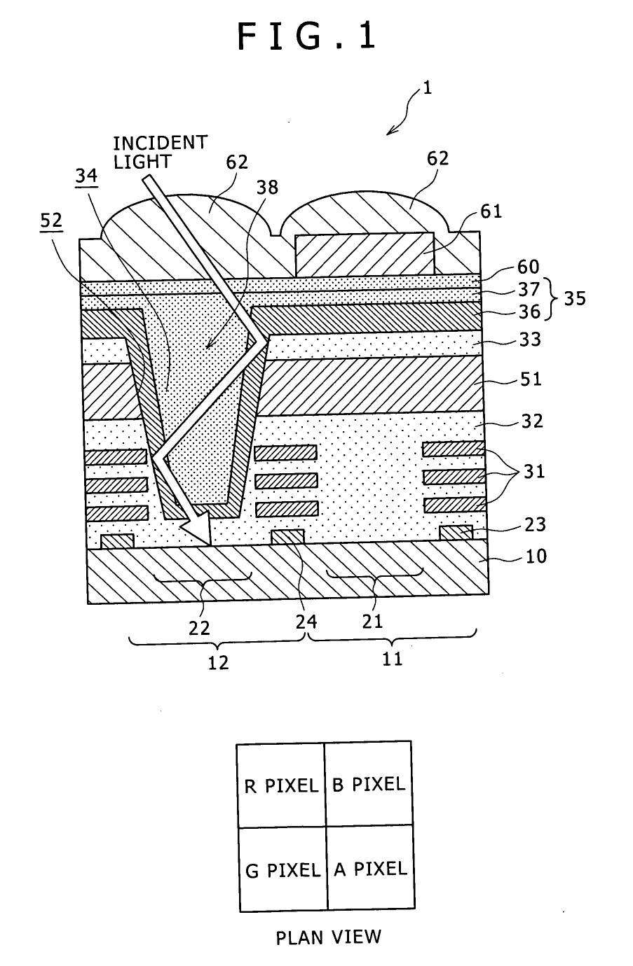

A solid-state image pickup device according to a first embodiment of the present invention will be described in detail hereinafter with reference to a schematically structural cross sectional view of FIG. 1.

As shown in FIG. 1, a light receiving portion 21 (for example, constituted by a photodiode) of a first pixel 11, a light receiving portion 22 (for example, constituted by a photodiode) of a second pixel 12, transistors 23 and 24 of the first pixel 11 and the second pixel 12, and the like are formed on a semiconductor substrate 10. Here, the first pixel 11 receives a visible light, and the second pixel 12 receives a near-infrared light and the visible light. For example, as shown in a lower side of FIG. 1, the first pixel 11 is composed of an R(Red) pixel for receiving a red light, a G(Green) pixel for receiving a green light, and a B(Blue) pixel for receiving a blue light. On the other hand, the second pixel 12 is composed of an A pixel for receiving the near-infrared light and the visible light. In the solid-state image pickup device 1, the pixels, for example, each having the four kinds of pixels described above as a set of pixels, for example, are disposed in matrix in a plane. It is noted that the first pixel 11 may be composed of complementary pixels of the R pixel, the G pixel and the B pixel, or a pixel having a color, in a visible light region, other than the colors described above, may be added to the first pixel 11.

In order to enhance the photoelectric conversion efficiency for the near-infrared light, in the second pixel 12, the photodiode constituting the light receiving portion 21 may be deeply formed.

Wirings 31, for example, forming a plurality of wiring layers, and an interlayer insulating film 32 covering the wirings 31 are formed over the first pixel 11 and the second pixel 12. The interlayer insulating film 32 is made of a material which transmits the near-infrared light and the visible light, for example, a high density plasma (HDP) oxide film or the like. These wirings 31 are disposed so as not to impede the optical paths of the incident lights made incident to the first pixel 11 and the second pixel 12, respectively. Also, a surface of the interlayer insulating film 32 is planarized.

An infrared light filter layer 51 for absorbing or reflecting the infrared light, and transmitting the visible light is formed on the interlayer insulating film 32 described above by combining materials such as a silicon oxide film, a silicon nitride film, a silicon carbide film, and a titanium oxide film with one another. The infrared light filter layer 51 realizes a filter function of selectively cutting the near-infrared light. Also, the infrared light filter layer 51 is formed in the form of the MLT film formed by laminating a plurality of layers having predetermined thicknesses, respectively, on top of one another. In the infrared light filter layer 51, each of the layers constituting the same is selected depending on its refractive index n and its reflection central wavelength λ. Thus, the infrared light filter layer 51 is formed by laminating a plurality of layers on top of one another by the number of layers allowing a necessary reflectivity to be realized.

Although the infrared light filter layer 51 described above is formed by laminating the plurality of film layers on top of one another, and a thickness thereof varies depending on the kinds of films and the optical characteristics of the films, the thickness thereof is approximately in the range of about 0.8 to about 1.5 μm. For example, for formation of the infrared light filter layer 51, a silicon nitride film having a thickness of 100 nm and a silicon oxide film having a thickness of 130 nm are alternately laminated on top of one another so as to obtain five layers of the silicon nitride films, and four layers of the silicon oxide films.

An opening portion 52 is selectively formed so as to extend completely through a position of the infrared light filter layer 51 corresponding to a portion above the second pixel 12, or an electrode portion (not shown).

Moreover, in order to planarize irregularities generated in the processes for forming the opening portion 52 so as to extend completely through the infrared light filter layer 51, an interlayer insulating film 33 having a planarized surface is formed so as to be filled in the opening portion 52. The interlayer insulating film 33 is made of the material which transmits the near-infrared light and the visible light, for example, the HDP oxide film or the like.

In addition, a hole 34 which is formed by utilizing the opening portion 52 is formed in the interlayer insulating films 33 and 32. The hole 34 is preferably formed to a depth near the semiconductor substrate 10 having the second pixel 12 formed thereon as much as possible. A shape of the hole 34 is preferably a cylindrical column or a quadrangular prism, and more preferably is a downward head-cut circular cone or a downward head-cut angular cone. Also, a high-refractive index material 35 is filled in the hole 34. The high-refractive index material 35, for example, may be an organic material such as siloxane, or an inorganic material such as a silicon nitride film. When each of the interlayer insulating films 32 and 33 formed to surround the periphery of the hole 34 is made of a silicon oxide, a refractive index of the high-refractive index material 35 needs to be preferably 1.6 or more, and is more preferably 1.8 or more because a refractive index of the silicon oxide is about 1.4.

A high-refractive index material film 37 made of an organic compound system material is formed so as to be filled in the hole 34 through a passivation film 36 made of a plasma silicon nitride film having a thickness of, for example, about 300 to about 1,000 nm. In this case, the high-refractive index material film 35 is composed of the passivation film 36 and the high-refractive index material film 37. As a result, forming the passivation film 36 from the plasma silicon nitride film results in that moisture resistance of the pixels is enhanced. The high-refractive index material film 37 is filled in the hole 34 through the passivation film 36 in such a manner, thereby forming an optical waveguide 38.

Moreover, an upper surface of the high-refractive index material film 37 is planarized, and an insulating film 60 is formed on the upper surface thereof. Also, a color filter layer 61 and a condenser lens 62 are formed on the insulating film 60. The color filter layer 61 is formed above the first pixel 11, that is, on an optical path of the incident light made incident to the first pixel 11, and is not formed on an optical path of the incident light made incident to the second pixel 12.

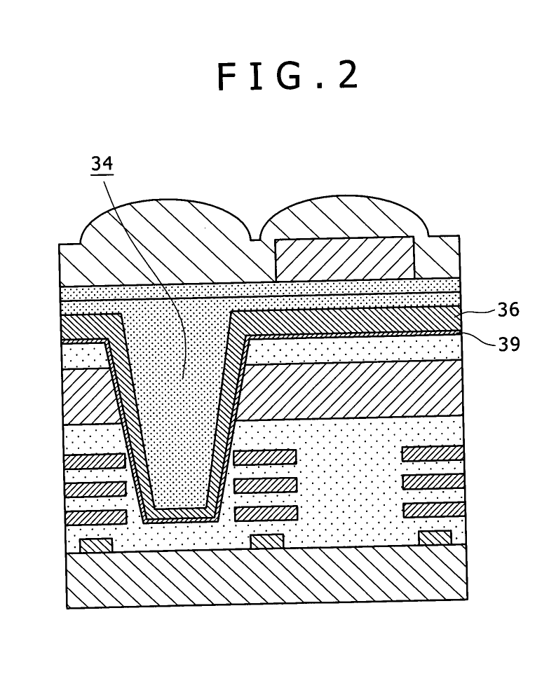

In addition, as shown in FIG. 2, a low-refractive index material film 39 having a lower refractive index than that of the interlayer insulating film 32 may be formed between an inner surface of the hole 34 and the passivation film 36.

In the solid-state image pickup device 1 having the structure described above, the infrared light filter layer 51 has the opening portion 52 formed by selectively opening the optical path of the incident light made incident to the second pixel 12. Also, the optical waveguide 38 for guiding the incident light in the direction to the second pixel 12 from the opening portion 52 is formed. Therefore, an influence of a color mixture component leaking from the second pixel 12 for receiving the visible light and the near-infrared light, and subjecting each of the visible light and the near-infrared light to the photoelectric conversion into the adjacent pixel is reduced, and thus a sensitivity of the second pixel 12 is enhanced. In addition, since the hole 34 can be selectively formed through the opening portion 52 with the infrared light filter layer 51 as a mask, there is an advantage that a bore diameter of the hole 34 can be increased at a maximum, and the hole can be formed in a self-aligned manner. As a result, it is possible to maximize a quantity of light guided to the second pixel 12 by the optical waveguide 38.

Consequently, the reduction of the influence of the color mixture component leaking from the second pixel 12 into the adjacent pixel prevents the problem about the color mixture from being caused even when the infrared light filter layer 51 for absorbing or reflecting the infrared light, and transmitting the visible light is formed. Therefore, there is an advantage that it is possible to suppress the deterioration of the color reproducibility. In addition, since the incident light can be efficiently condensed on the second pixel 12 by the optical waveguide 38, there is an advantage that it is possible to realize the high sensitivity.

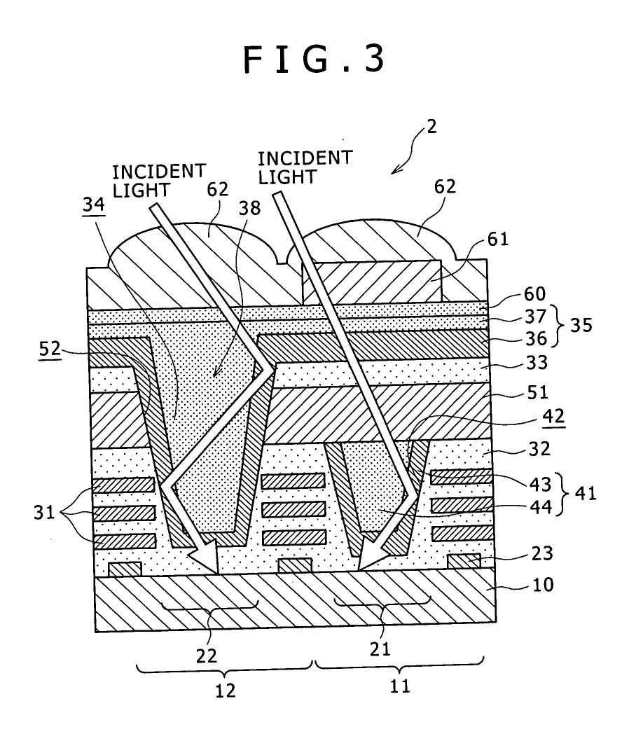

Next, a solid-state image pickup device according to a second embodiment of the present invention will be described with reference to a schematically structural cross sectional view of FIG. 3. In the solid-state image pickup device 2 of the second embodiment, an optical waveguide is provided above the first pixel 11 of the solid-state image pickup device 1 which has already been described with reference to FIG. 1.

As shown in FIG. 3, similarly to the case of the solid-state image pickup device 1 of the first embodiment, the light receiving portion 21 (for example, constituted by a photodiode) of the first pixel 11, the light receiving portion 22 (for example, constituted by a photodiode) of the second pixel 12, the transistors 23 and 24 of the first pixel 11 and the second pixel 12, and the like are formed on the semiconductor substrate 10. Here, the first pixel 11 receives the visible light, and the second pixel 12 receives the near-infrared light and the visible light. For example, the first pixel 11 is composed of the three pixels, that is, the R pixel for receiving the read light, the G pixel for receiving the green light, and the B pixel for receiving the blue light. On the other hand, the second pixel 12 is composed of the A pixel for receiving the near-infrared light and the visible light. In the solid-state image pickup device 2, the pixels, for example, each having the four kinds of pixels described above as a set of pixels, for example, are disposed in matrix in a plane. It is noted that the first pixel 11 may be composed of the complementary pixels of the R pixel, the G pixel and the B pixel, or the pixel having the color, in the visible light region, other than the colors described above, may be added to the first pixel 11.

The wirings 31, for example, forming a plurality of wiring layers, and the interlayer insulating film 32 covering the wirings 31 are formed over the first pixel 11 and the second pixel 12. The interlayer insulating film 32 is made of the material which transmits the near-infrared light and the visible light, for example, the HDP oxide film or the like. These wirings 31 are disposed so as not to impede the optical paths of the incident lights made incident to the first pixel 11 and the second pixel 12, respectively. Also, the surface of the interlayer insulating film 32 is planarized.

An optical waveguide 41 which leads to a direction to the first pixel 11 is formed in the interlayer insulating film 32 described above. The optical waveguide 41 has the same structure as that of the optical waveguide 38 described above. For example, the optical waveguide 41 is formed by filling a material having a higher refractive index than that of the interlayer insulating film 32 in a hole 42 which is formed above the first pixel 11. For example, the optical waveguide 41 is formed by filling a high-refractive index material film 44 in the hole 42 through a passivation film 43 made of a high-refractive index material. The passivation film 43, for example, is formed from a plasma silicon nitride film having a thickness of about 300 to about 1,000 nm. Also, the high-refractive index material film 44, for example, is made of an organic compound system material. In this case, the optical waveguide 41 is composed of the passivation film 43 and the high-refractive index material film 44. As a result, forming the passivation film 43 from the plasma silicon nitride film results in that the moisture resistance of the pixels is enhanced. The high-refractive index material film 44 is filled in the hole 42 through the passivation film 43 in such a manner, thereby forming the optical waveguide 41.

The hole 42 is preferably formed to a depth near the semiconductor substrate 10 having the first pixel 11 formed thereon as much as possible. A shape of the hole 42 is preferably a cylindrical column or a quadrangular prism, and more preferably is a downward head-cut circular cone or a downward head-cut angular cone. In addition, the material film (not shown) having a lower refractive index than that of the interlayer insulating film 32 may be formed between an inner surface of the hole 42 and the passivation film 43 similarly to the case of the optical waveguide 38 which is previously described with reference to FIG. 2.

In addition, the passivation film 43 made of the high-refractive index material, and the high-refractive index material film 44 are preferably made of materials each having high heat resistance.

The infrared light filter layer 51 for absorbing or reflecting the infrared light, and transmitting the visible light is formed on the interlayer insulating film 32. The opening portion 52 is formed so as to extend completely through a position of the infrared light filter layer 51 corresponding to the portion above the second pixel 12, or the electrode portion (not shown). Moreover, in order to planarize the irregularities generated in the process for forming the opening portion 52 so as to extend completely through in the infrared light filter layer 51, the interlayer insulating film 33 having the planarized surface is formed so as to be filled in the opening portion 52. The interlayer insulating film 33 is made of a material which transmits the near-infrared light and the visible light, for example, the HDP oxide film or the like.

In addition, the hole 34 which is formed by utilizing the opening portion 52 is formed in the interlayer insulating films 33 and 32. The hole 34 is preferably formed to the depth near the semiconductor substrate 10 having the second pixel 12 formed thereon as much as possible. The shape of the hole 34 is preferably a cylindrical column or a quadrangular prism, and more preferably is a downward head-cut circular cone or a downward head-cut angular cone. Also, the high-refractive index material 35 is filled in the hole 34. The high-refractive index material 35, for example, may be an organic material such as siloxane, or an inorganic material such as a silicon nitride film. When each of the interlayer insulating films 32 and 33 formed to surround the periphery of the hole 34 is made of a silicon oxide, the refractive index of the high-refractive index material 35 needs to be preferably 1.6 or more, and is more preferably 1.8 or more because the refractive index of the silicon oxide is about 1.4.

The high-refractive index material film 37 made of an organic compound system material is formed so as to be filled in the hole 34 through the passivation film 36 formed from a plasma silicon nitride film having a thickness of, for example, about 300 to about 1,000 nm. In this case, the high-refractive index material film 35 is composed of the passivation film 36 and the high-refractive index material film 37. As a result, forming the passivation film 36 from the plasma silicon nitride film results in that the moisture resistance of the pixels is enhanced. The high-refractive index material film 37 is filled in the hole 34 through the passivation film 36 in such a manner, thereby forming the optical waveguide 38.

Moreover, the upper surface of the high-refractive index material film 37 is planarized, and the insulating film 60 is formed on the upper surface thereof. Also, the color filter layer 61 and the condenser lens 62 are formed on the insulating film 60. The color filter layer 61 is formed above the first pixel 11, that is, on the optical path of the incident light made incident to the first pixel 11, and is not formed on the optical path of the incident light made incident to the second pixel 12.

In the solid-state image pickup device 2 having the structure described above, the infrared light filter layer 51 has the opening portion 52 formed by selectively opening the optical path of the incident light made incident to the second pixel 12. Also, the optical waveguide 38 for guiding the incident light in the direction to the second pixel 12 from the opening portion 52 is formed. Therefore, the influence of the color mixture component leaking from the second pixel 12 for receiving the visible light and the near-infrared light, and subjecting each of the visible light and the near-infrared light to the photoelectric conversion into the adjacent pixel is reduced, and thus the sensitivity of the second pixel 12 is enhanced. In addition, since the hole 34 can be formed through the opening portion 52 with the infrared light filter layer 51 as the mask, there is the advantage that the bore diameter of the hole 34 can be increased at a maximum, and the hole 34 can be formed in a self-aligned manner. As a result, it is possible to maximize the quantity of light guided to the second pixel 12 by the optical waveguide 38.

Consequently, the reduction of the influence of the color mixture component leaking from the second pixel 12 into the adjacent pixel prevents the problem about the color mixture from being caused even when the infrared light filter 51 for absorbing or reflecting the infrared light, and transmitting the visible light is formed. Therefore, there is the advantage that it is possible to suppress the deterioration of the color reproducibility. In addition, since the incident light can be efficiently condensed on the second pixel 12 by the optical waveguide 38, there is the advantage that it is possible to increase the sensitivity.

Moreover, since the optical waveguide 41 is formed on the light incidence side of the first pixel 11, it is possible to improve the light condensing state as well in the first pixel 11. Therefore, the deterioration of the color reproducibility is further suppressed, and thus it becomes possible to increase the sensitivity of the solid-state image pickup device.

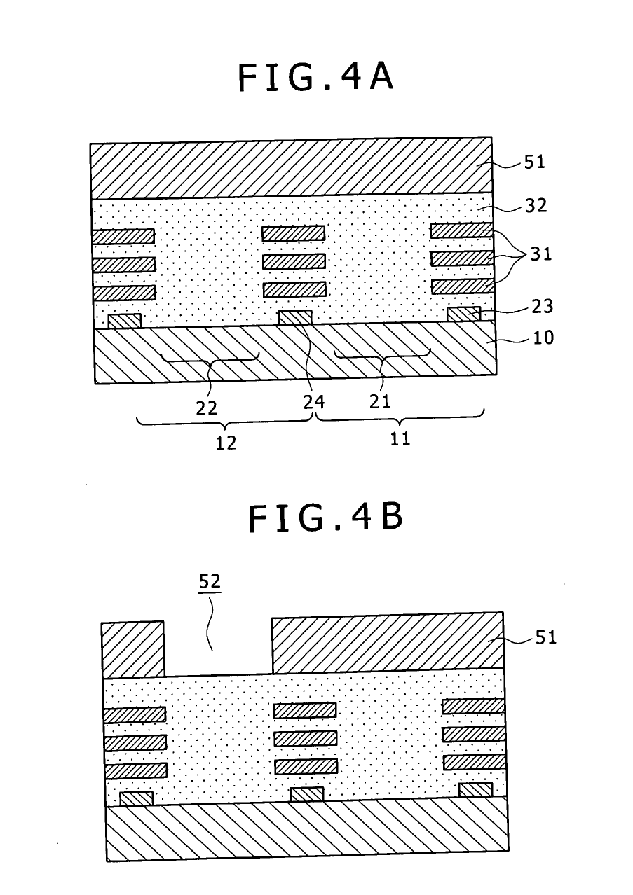

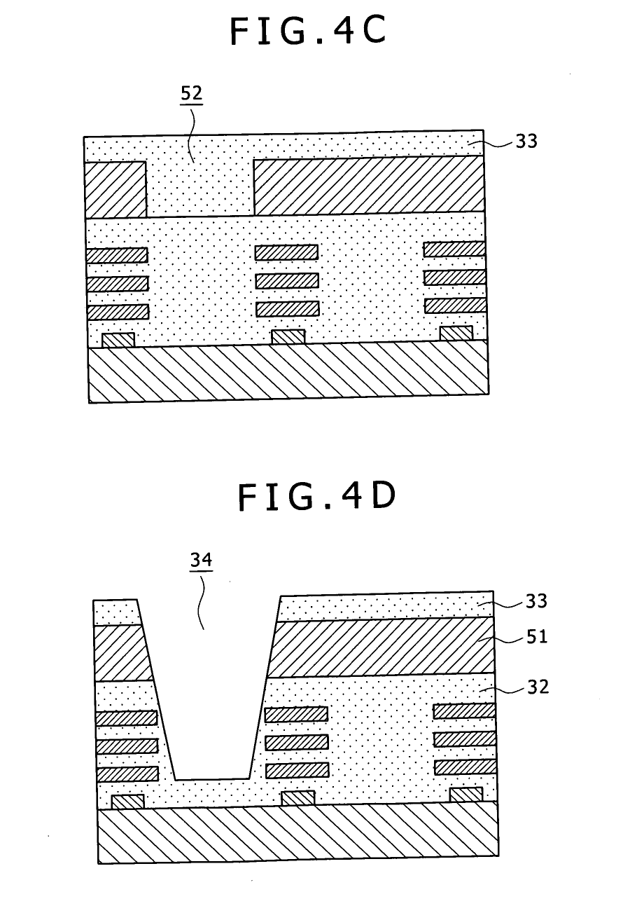

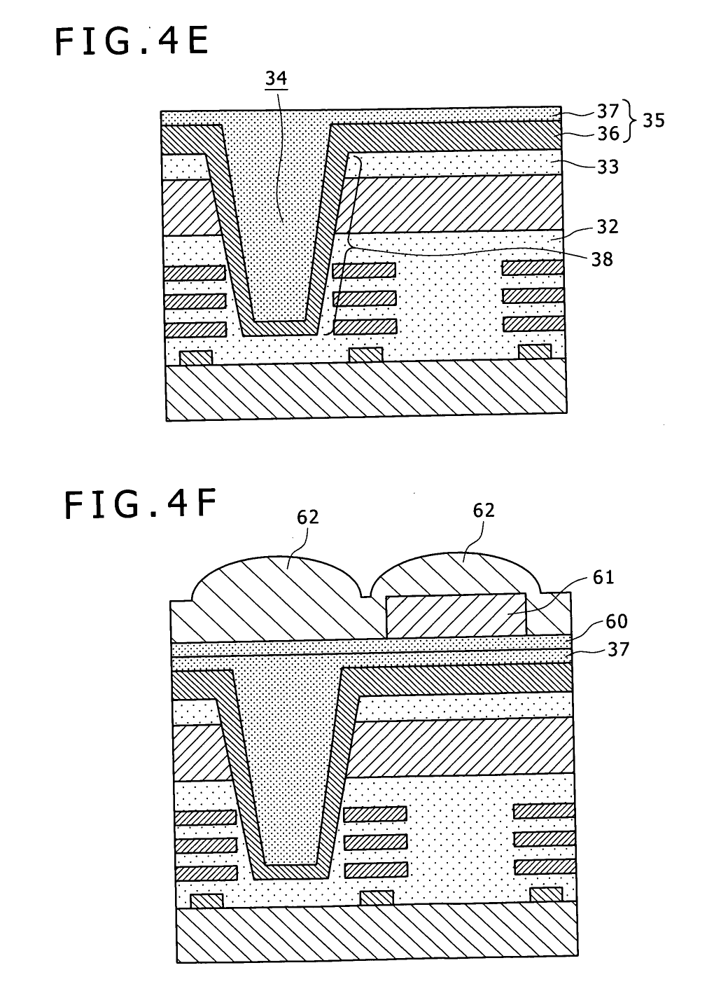

Next, a method of manufacturing the solid-state image pickup device according to a first embodiment of the present invention will be described in detail with reference to FIGS. 4A to 4F.

As shown in FIG. 4A, firstly, the light receiving portion 21 (for example, constituted by the photodiode) of the first pixel 11, the light receiving portion 22 (for example, constituted by the photodiode) of the second pixel 12, the transistors 23 and 24 of the first pixel 11 and the second pixel 12, and the like are formed on the semiconductor substrate 10 by utilizing the known manufacturing method. Here, the first pixel 11 receives the visible light, and the second pixel 12 receives the near-infrared light and the visible light. In this case, in order to enhance the photoelectric conversion efficiency for the near-infrared light, in the second pixel 12, the photodiode constituting the light receiving portion 21 may be deeply formed.

Next, the wirings 31 constituting the first pixel 11 and the second pixel 12, and the interlayer insulating film 32 covering the wirings 31 are formed. These wirings 31 are disposed so as not to impede the optical paths of the incident lights made incident to the first pixel 11 and the second pixel 12, respectively. Next, the surface of the interlayer insulating film 32 overlying the wirings 31 is planarized by performing chemical mechanical polishing (CMP) processing or the like.

Subsequently, the infrared light filter layer 51 for absorbing or reflecting the infrared light, and transmitting the visible light is formed on the interlayer insulating film 32 described above by combining materials such as a silicon oxide film, a silicon nitride film, a silicon carbide film, and a titanium oxide film with one another. The infrared light filter layer 51 realizes the described filter function of selectively cutting the near-infrared light. Also, the infrared light filter layer 51 is formed in the form of the MLT film formed by laminating a plurality of layers having predetermined thicknesses, respectively, on top of one another. In the infrared light filter layer 51, each of the layers constituting the same is selected depending on its refractive index n and its reflection central wavelength λ. Thus, the infrared light filter layer 51 is formed by laminating a plurality of layers on top of one another by the number of layers allowing the necessary reflectivity to be realized.

Although the infrared light filter layer 51 described above is formed by laminating the plurality of film layers on top of one another, and the thickness thereof varies depending on the kinds of films and the optical characteristics of the films, the thickness thereof is approximately in the range of about 0.8 to about 1.5 μm.

Next, as shown in FIG. 2B, there is formed a resist mask (not shown) which is selectively opened so as to correspond in position to the second pixel 12, an electrode (not shown), and the like, respectively. Also, an unnecessary portion of the infrared light filter layer 51 is removed by performing dry etching processing, thereby forming the opening portion 52.

Next, as shown in FIG. 4C, in order to planarize the irregularities generated by the patterning for formation of the opening portion 52, the interlayer insulating film 33 formed from the HDP oxide film or the like is deposited so as to be filled in the opening portion 52. Also, the surface of the interlayer insulating film 33 is planarized by performing the CMP processing again.

Next, as shown in FIG. 4D, a resist mask (not shown) which is selectively opened so as to correspond in position to only the second pixel 12 is formed on the interlayer insulating film 33. Also, portions, of the interlayer insulating films 32 and 33, which are formed above the second pixel 12 are removed, and a part, of the infrared light filter layer 51, which is formed above the second pixel 12 is also removed as the case may be, thereby forming the hole 34. The hole 34 is preferably formed to the depth near the semiconductor substrate 10 having the second pixel 12 formed thereon as much as possible. The shape of the hole 34 is preferably a cylindrical column or a quadrangular prism, and more preferably is a downward head-cut circular cone or a downward head-cut angular cone. As a result, it becomes easy to perform the subsequent processes for filling the passivation films 36 and the high-refractive index material film 37 in the hole 34.

Next, as shown in FIG. 4E, the high-refractive index material film 35 is filled in the hole 34. The high-refractive index material 35, for example, may be an organic material such as siloxane, or an inorganic material such as a silicon nitride film. When each of the interlayer insulating films 32 and 33 formed to surround the periphery of the hole 34 is made of a silicon oxide, the refractive index of the high-refractive index material 35 needs to be preferably 1.6 or more, and is more preferably 1.8 or more because a refractive index of the silicon oxide is about 1.4.

In this case, in order to form the high-refractive index material film 35, after the plasma silicon nitride film becoming the passivation film 36 is deposited to have the thickness of about 300 to about 1,000 nm, the high-refractive index material film 37 made of the organic compound system material is formed so as to be filled in the hole 34. As a result, forming the passivation film 36 from the plasma silicon nitride film results in that the moisture resistance of the pixels is enhanced. The high-refractive index material film 37 is filled in the hole 34 through the passivation film 36 in such a manner, thereby forming the optical waveguide 38.

Next, as shown in FIG. 4F, after the upper surface of the high-refractive index material film 37 is planarized, the insulating film 60 is formed on the upper surface of the high-refractive index material film 37. Also, the color filter 61, the condenser lens 62, and the like are formed on the insulating film 60.

In addition, as shown in FIG. 2, the low-refractive index material film 39 having a lower refractive index than that of the interlayer insulating film 32 may be formed between the inner surface of the hole 34 and the passivation film 36.

In the manufacturing method according to the first embodiment of the present invention, the opening portion 52 is selectively formed in the optical path, in the infrared light filter layer 51, of the incident light made incident to the second pixel 12. Also, the optical waveguide 38 for guiding the incident light in the direction to the second pixel 12 is formed by utilizing the opening portion 52. Therefore, the influence of the color mixture component leaking from the second pixel 12 for receiving the visible light and the near-infrared light, and subjecting each of the visible light and the near-infrared light to the photoelectric conversion into the adjacent pixel is reduced, and thus the sensitivity of the second pixel 12 is enhanced.

Consequently, the reduction of the influence of the color mixture component leaking from the second pixel 12 into the adjacent pixel prevents the problem about the color mixture from being caused even when the infrared light filter 51 for absorbing or reflecting the infrared light, and transmitting the visible light is formed. Therefore, there is the advantage that it is possible to suppress the deterioration of the color reproducibility. In addition, since the incident light can be efficiently condensed on the second pixel 12 by the optical waveguide 38, there is the advantage that it is possible to increase the sensitivity.

In addition, since the hole 34 can be selectively formed through the opening portion 52 with the infrared light filter layer 51 as the mask, there is the advantage that the bore diameter of the hole 34 can be increased at a maximum, and the hole 34 can be formed in the self-aligned manner. As a result, it is possible to maximize the quantity of light guided to the second pixel 12 by the optical waveguide 38.

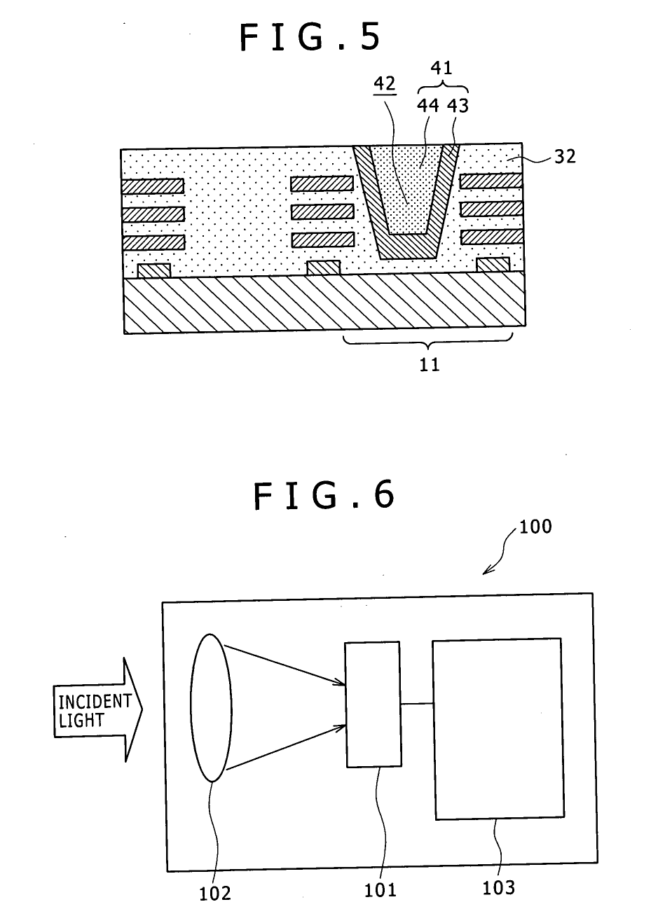

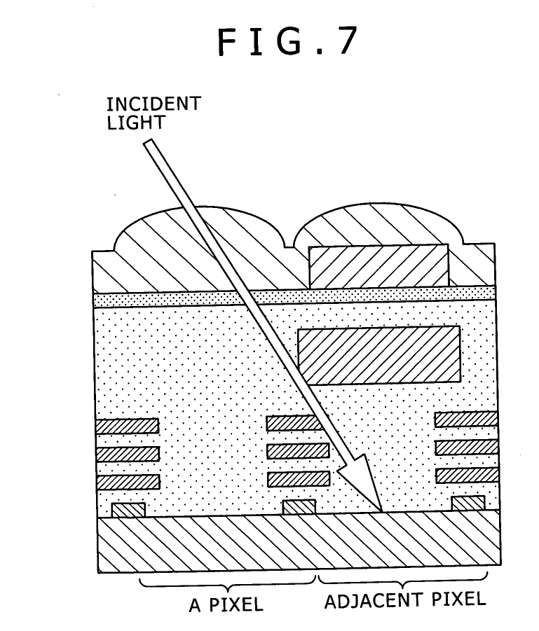

Next, a method of manufacturing the solid-state image pickup device according to a second embodiment of the present invention will be described with reference to a cross sectional view of FIG. 5 showing manufacturing processes. The manufacturing method of the second embodiment is the method of manufacturing the solid-state image pickup device 2 of the second embodiment described with reference to FIG. 3.

As shown in FIG. 5, before the infrared light filter 51 described with reference to FIGS. 4A to 4F of the first embodiment described above is formed after completion of the formation of the interlayer insulating film 32, the optical waveguide 41 which leads to the direction to the first pixel 11 is formed in the interlayer insulating film 32. A method of forming the optical waveguide 41 is the same as that of forming the optical waveguide 38 so as to lead to the second pixel 12. For example, after the hole 42 which leads to the direction to the first pixel 11 is formed in the interlayer insulating film 32, the material having a higher refractive index than that of the interlayer insulating film 32 is filled in the hole 42, thereby forming the optical waveguide 41. For example, after the plasma silicon nitride film becoming the passivation film 43 is deposited as the high-refractive index material to have a thickness of about 300 to about 1,000 nm by utilizing the CVD method, the high-refractive index material film 44 made of the organic compound system material is formed so as to be filled in the hole 42 through the passivation film 43. As a result, forming the passivation film 43 from the plasma silicon nitride film results in that the moisture resistance of the pixels is enhanced. The high-refractive index material film 44 is filled in the hole 42 through the passivation film 43 in such a manner, thereby forming the optical waveguide 41.

The hole is preferably formed to the depth near the semiconductor substrate 10 having the second pixel 12 formed thereon as much as possible. The shape of the hole 42 is preferably a cylindrical column or a quadrangular prism, and more preferably is a downward head-cut circular cone or a downward head-cut angular cone. As a result, it becomes easy to perform the subsequent processes for filling the passivation film 43 and the high-refractive index material film 44 in the hole 42. In addition, the material film (not shown) having a lower refractive index than that of the interlayer insulating film 32 may be formed between the inner surface of the hole 42 and the passivation film 43 similarly to the case of the optical waveguide 38 which is previously described with reference to FIG. 2.

After that, the processes described in the first embodiment are performed, thereby performing formation of the optical waveguide 38 above the second pixel 12, and the like.

Each of the passivation film 43 as the high-refractive index material described above, and the high-refractive index material film 44 are preferably made of the materials each having the high heat resistance, respectively, in consideration of a heat treatment in the late manufacturing process.

In the manufacturing method according to the second embodiment of the present invention, the opening portion 52 is selectively formed in the optical path, in the infrared light filter layer 51, of the incident light made incident to the second pixel 12. Also, the optical waveguide 38 for guiding the incident light in the direction to the second pixel 12 is formed by utilizing the opening portion 52. Therefore, the influence of the color mixture component leaking from the second pixel 12 for receiving the visible light and the near-infrared light, and subjecting each of the visible light and the near-infrared light to the photoelectric conversion into the adjacent pixel is reduced, and thus the sensitivity of the second pixel 12 is enhanced. Consequently, the reduction of the influence of the color mixture component leaking from the second pixel 12 into the adjacent pixel prevents the problem about the color mixture from being caused even when the infrared light filter 51 for absorbing or reflecting the infrared light, and transmitting the visible light is formed. Therefore, there is the advantage that it is possible to suppress the deterioration of the color reproducibility. In addition, since the incident light can be efficiently condensed on the second pixel 12 by the optical waveguide 38, there is the advantage that it is possible to increase the sensitivity.

In addition, since the hole 34 can be selectively formed through the opening portion 52 with the infrared light filter layer 51 as the mask, there is the advantage that the bore diameter of the hole 34 can be increased at a maximum, and the hole can be formed in the self-aligned manner. As a result, it is possible to maximize a quantity of light guided to the second pixel 12 by the optical waveguide 38.

Moreover, since the optical waveguide 41 is formed on the light incidence side of the first pixel 11, it is possible to improve the light condensing state as well in the first pixel 11. Therefore, the deterioration of the color reproducibility is further suppressed, and thus it becomes possible to increase the sensitivity of the solid-state image pickup device.

The infrared light filter layer 51 in each of the embodiments described above may be a section to which only the visible light is made incident, for example, a section which avoids the incidence of the near-infrared light to each of the RGB pixels. Thus, the infrared light filter layer 51 may be made of either an infrared light reflecting material or an infrared light absorbing material.

The first pixel 11 in each of the embodiments described above, for example, may be composed of the R(Red) pixel, the G(Green) pixel, and the B(Blue) pixel, or may be composed of the complementary pixels thereof. Or, the pixel having the color, in the visible light region, other than the colors described above, may be added to the first pixel 11.

Next, an image pickup apparatus according to an embodiment of the present invention will be described with reference to a block diagram of FIG. 6. A video camera, a digital still camera, a camera for a mobile phone, or the like, for example, is known as the image pickup apparatus.

As shown in FIG. 6, the image pickup apparatus 100 includes a solid-state image pickup device (not shown) provided in an image pickup portion 101. An imaging optical system 102 for imaging an image is provided on a light condensing side of the image pickup portion 101. In addition, a signal processing portion 103 having a driving circuit for driving the image pickup portion 101, a signal processing circuit for processing a signal obtained through the photoelectric conversion in the solid-state image pickup device into an image signal, and the like is connected to the image pickup portion 101. Also, the image signal obtained in the processing executed in the signal processing portion 103 can be stored in an image storing portion (not shown). In such an image pickup apparatus 100, either the solid-state image pickup device 1 or solid-state image pickup device 2 which has been described in corresponding one of the embodiments described above can be used as the solid-state image pickup device.

The solid-state image pickup device 1 or solid-state image pickup device 2 which has been described in corresponding one of the embodiments of the present invention is used in the image pickup apparatus 100, which leads to that the solid-state image pickup device capable of enhancing the color reproducibility and the sensitivity is used similarly to each of the embodiments described above. Consequently, there is an advantage that an image of high grade can be recorded at the high sensitivity in the image pickup apparatus 100.

It is noted that the configuration of the image pickup apparatus 100 according to the embodiment of the present invention is by no means limited to the configuration described above, and thus the image pickup apparatus 100 can be applied to an apparatus having any configuration as long as the apparatus is an image pickup apparatus using the solid-state image pickup device.

The solid-state image pickup device 1, 2 or the like may has a form in which the solid-state image pickup device 1, 2 or the like is formed in the form of one chip, or may have a module-like form, having the image pickup function, in which the image pickup portion, and the signal processing portion or the optical system are collectively packaged. In addition, the present invention can be applied not only to the solid-state image pickup device, but also to the image pickup apparatus. In this case, the image pickup apparatus offers an effect of realizing the high-image quality. Here, the image pickup apparatus means a mobile apparatus having a camera or an image pickup function. In addition, the wording “image pickup” means not only the capturing of an image in the phase of the normal photographing using the camera, but also the fingerprint detection and the like in a broad sense.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state image pickup device, comprising:
a first pixel for receiving a visible light of an incident light to subject the visible light to photoelectric conversion;
a second pixel for receiving the visible light and a near-infrared light of the incident light to subject each of the visible light and the near-infrared light to the photoelectric conversion;
a color filter layer; and
an infrared light filter layer for absorbing or reflecting an infrared light, and transmitting the visible light;
wherein said color filter layer and said infrared light filter layer are formed in order from a light incidence side of an optical path of the incident light made incident to said first pixel,
said infrared light filter layer has an opening portion formed by opening an optical path of the incident light made incident to said second pixel, and
an optical waveguide for guiding the incident light in a direction to said second pixel through said opening portion is formed.

2. The solid-state image pickup device according to claim 1, further comprising
an optical waveguide leading to a direction from a lower portion of said infrared light filter layer to said first pixel.

3. A method of manufacturing a solid-state image pickup device having a substrate, a first pixel for receiving a visible light of an incident light to subject the visible light to photoelectric conversion, a second pixel for receiving the visible light and a near-infrared light of the incident light to subject each of the visible light and the near-infrared light to the photoelectric conversion, and an optically-transparent insulating film covering said first pixel and said second pixel being formed on said substrate, said method of manufacturing a solid-state image pickup device comprising the steps of:
forming an infrared light filter layer for absorbing or reflecting an infrared light, and transmitting the visible light in a region except for an optical path of the incident light made incident to said second pixel, said region being located on said insulating film;
forming an opening portion in the optical path of the incident light made incident to said second pixel so as to extend completely through said infrared light filter layer; and
forming an optical waveguide for guiding the incident light in a direction to said second pixel through said opening portion in said optically-transparent insulating film by utilizing said opening portion.

4. An image pickup apparatus, comprising:
a condensing optical portion for condensing an incident light;
a solid-state image pickup device for receiving the incident light condensed by said condensing optical portion to subject the condensed incident light thus received to photoelectric conversion; and
a signal processing portion for processing a signal obtained through the photoelectric conversion;
wherein said solid-state image pickup device includes
a first pixel for receiving a visible light of an incident light to subject the visible light to photoelectric conversion,
a second pixel for receiving the visible light and a near-infrared light of the incident light to subject each of the visible light and the near-infrared light to the photoelectric conversion,
a color filter layer, and
an infrared light filter layer for absorbing or reflecting an infrared light, and transmitting the visible light,
said color filter layer and said infrared light filter layer are formed in order from a light incidence side of an optical path of the incident light made incident to the first pixel,
said infrared light filter layer has an opening portion formed by opening an optical path of the incident light made incident to said second pixel, and
an optical waveguide for guiding the incident light in a direction to said second pixel through the opening portion is formed.
